(19) United States
(12) Patent Application Publication
(10) Pub. No.: US 2025/0372476 A1
(43) Pub. Date: Dec. 4, 2025

(54) HEAT SPREADER WITH REDISTRIBUTION LAYER

(71) Applicant: International Business Machines Corporation, Armonk, NY (US)

(72) Inventors: John Knickerbocker, Monroe, NY (US); Mukta Ghate Farooq, Hopewell Junction, NY (US); Keiji Matsumoto, Yokohama-shi (JP); John W. Golz, Hopewell Junction, NY (US)

(21) Appl. No.: 18/731,983

(22) Filed: Jun. 3, 2024

(51) Int. Cl. H01L 23/367; H01L 23/00; H01L 23/498; H01L 25/065

(52) U.S. Cl. CPC H01L 23/3675; H01L 23/49816; H01L 23/49822; H01L 24/08; H01L 24/16; H01L 25/0657; H01L 2224/08146; H01L 2224/08225; H01L 2224/16146; H01L 2224/16227; H01L 2225/06517; H01L 2225/06541; H01L 2924/01013; H01L 2924/01029; H01L 2924/15311; H01L 2924/18161; H01L 2924/351

(57) ABSTRACT

A semiconductor package includes a substrate such as an organic laminate substrate having conductors for carrying signals and includes an integrated circuit (IC) chip, e.g., a 3-dimensional flip-chip IC stack mounted thereon. The flip-chip is electrically connected to exposed conductors at the organic laminate substrate for receiving power signals and ground therefrom. A thermally conductive heat spreader with a redistribution layer (RDL) of high thermal conductive material for power delivery and heat spreading is connected to a top surface of the IC chip. In an example, the RDL can electrically connect with the laminate below the chip and at the peripheral of the chip. The thermally conductive heat spreader structure is disposed on top the RDL layer for receiving, distributing and dissipating heat from a top surface of the RDL. The package enables improved power delivery, heat spreading and heat removal from a top side of the IC chip.

### FIELD

The present disclosure relates generally to high-performance chip stacks, and the packaging thereof, and more particularly, improvements to a type of laminate referred to as a “thermal power plane” including the addition of a redistribution layer of dielectric material upon a heat spreader to enable improved power delivery, heat spreading and heat removal from a chip top side.

### BACKGROUND

Heat dissipation in semiconductor devices and semiconductor integrated circuits (IC) has continued to gain an increasing interest in recent years due to the miniaturization of semiconductor devices. The temperature increase becomes relevant for cases of relatively small-cross-sections wires, because such temperature increase may affect the normal behavior of semiconductor devices.

As integrated circuit technology continues to evolve, manufacturing processes continue to improve to allow for increases in density and operating frequency of ICs. These improvements are driven by a steady demand for high speed data processing. However, these advances have also resulted in ICs that produce significantly increased heat generation per unit time per unit volume.

Therefore, just how to provide the semiconductor package with even more effective heat-dissipating path has become an important issue in order to improve the performance and maintain the reliability of the semiconductor devices.

### SUMMARY

The present disclosure relates to a packaging structure for a semiconductor integrated circuit chip configured to improve both power delivery and thermal management.

The present disclosure improves both power delivery and thermal management in a dual- or multi-die chip stack structure by integrating a re-distribution layer (RDL) of high thermal conductive material and a heat spreader, namely a RDL of dielectric material fabricated on the heat spreader.

In an embodiment, the RDL is of a highly thermally conductive material and can be a dielectric material, including but not limited to: silicon dioxide, silicon nitride, silicon oxynitride, boron nitride, aluminum nitride, beryllium oxide, diamond film (diamond-like carbon) or any multilayered combination thereof.

In one aspect, the RDL is electrically connected with an organic laminate substrate below a chip, at the peripheral of a chip, to provide for routing of the power and ground.

In another aspect, the packaging structure includes an organic laminate substrate that delivers power and ground to both the bottom of a chip or chiplet and to the top of a chip or chiplet.

In another aspect, the packaging structure includes an organic laminate substrate that delivers power and ground to both the bottom chip of chip stacks or chiplet stacks and to the top chip of chip stacks or chiplet stacks.

In another aspect, the packaging structure further includes an electrical interconnect between an organic laminate substrate and RDL that is filled with a highly thermal conductive material (e.g., underfill, molding compound).

In an embodiment, the organic laminate substrate is coreless or has a metal core and/or embedded graphite sheets.

In one aspect, there is provided an apparatus. The apparatus comprises: an organic laminate substrate having spaced apart raised laminate portions to define a cavity therebetween, the organic laminate substrate including conductive connectors at a surface of the cavity and at a surface of one of the raised laminate portions for carrying signals; a semiconductor integrated circuit (IC) chip mounted within the cavity and electrically connected to exposed conductors at a surface of the cavity, the IC chip having top surface conductive connections; and a layered structure comprising: a redistribution layer (RDL) of high thermal conductive material disposed overlying the IC chip and overlying at least one of the spaced apart raised laminate portions, the RDL having a bottom surface with conductor elements electrically connecting to corresponding aligned conductive connections at a top surface of the IC chip and further connected to the conductive connectors at a top surface of the raised laminate portion and having conductors for redistributing signals received from the organic laminate substrate for input to the IC chip; and a heat spreader layer disposed on a top surface of the RDL layer for receiving, distributing and dissipating heat from the top surface of the RDL.

In a further aspect, there is provided an apparatus. The apparatus comprises: a substrate having conductors for carrying signals; a semiconductor integrated circuit (IC) chip mounted on and electrically connected to exposed conductors at said substrate for receiving signals therefrom; a redistribution layer (RDL) of high thermal conductive material connected to a top surface of said IC chip, said RDL having connector structures for electrical connection with conductors of said substrate for receiving signals from the substrate and distributing the signals to said IC chip; and a thermally conductive heat spreader structure disposed on top said RDL layer for receiving, distributing and dissipating heat from a top surface of the RDL.

In a further aspect, there is provided a method for manufacturing a flip-chip package. The method comprises: fabricating a redistribution layer (RDL) of high thermal conductive material on a heat spreader structure; physically joining, to an organic laminate substrate, a semiconductor flip-chip stack assembly comprising at least a top integrated circuit (IC) chip and a bottom IC chip, the organic laminate substrate having spaced apart raised laminate portions to define a cavity therebetween, wherein the semiconductor flip-chip stack assembly bottom IC chip is joined at the defined cavity for electrical connection to the organic laminate substrate; and physically joining the fabricated redistribution layer (RDL) and heat spreader structure on a top surface of the top IC chip and a top surface of each the raised laminate portions of the organic laminate substrate for electrical connection therewith, wherein the RDL comprises a bottom surface with conductor elements electrically connecting to corresponding aligned conductive connections at a top surface of the top IC chip and further connected to the conductive connectors at a top surface of the raised laminate portions and comprises conductors for redistributing signals received from the organic laminate substrate for input to the top IC chip.

Further features as well as the structure and operation of various embodiments are described in detail below with reference to the accompanying drawings. In the drawings, like reference numbers indicate identical or functionally similar elements.

### BRIEF DESCRIPTION OF THE DRAWINGS

FIG. 1A depicts a cross-sectional view of a conventional semiconductor IC package or module including a flip chip assembly such as a two-die chip stack where a bottom IC of the flip chip electrically connects to a substrate, such as an organic laminate via a series of C4 or solder bump connections;

FIG. 1B depicts a cross-sectional view of a further conventional semiconductor IC package or module including a flip chip assembly such as a two-die chip stack and including a “thermal power plane” functioning both as a means of power delivery of power signals to the top IC chip and also as a heat spreader for spreading/dissipating of heat generated by the chip stack;

FIG. 2 shows an improved embodiment of a semiconductor chip package assembly for a flip chip IC chip stack assembly including a combined redistribution layer RDL/heat spreader structure according to an embodiment;

FIG. 3A shows the separate step of forming of the power delivery and heat dissipating structure for the packaging assembly of FIG. 2;

FIGS. 3B-3E depict a method for forming the semiconductor chip package of FIG. 2 that includes the flip chip assembly or multi-die or two-die chip stack and the further connected separately formed power delivery and heat dissipating structure consisting of the heat spreader layer and underlying dielectric redistribution layer (RDL); and

FIG. 4 depicts a further structure resulting from further packaging and assembly to attach one or more structures of FIG. 3E to a printed wiring board or printed circuit board, e.g., using a solder reflow process.

### DETAILED DESCRIPTION

In a semiconductor device assembly, some semiconductor chips (also referred to as an integrated circuit (IC) chip or “chiplet” or “die”) have reached a density level that can make it difficult for making connections to and from the chip. Therefore, many such devices include a redistribution layer (RDL) and with ball-shaped beads or bumps of solder for forming electrical connections to and from the chip and conductive traces on a packaging substrate. Semiconductor chips of this type are commonly called “flip chips.”

The present disclosure relates to a novel heat spreader unit including redistribution layer formed on top surface of an integrated circuit (IC) chip/chiplet/flip-chip for improved power delivery, heat spreading and heat removal from the chip (or chiplet) top side.

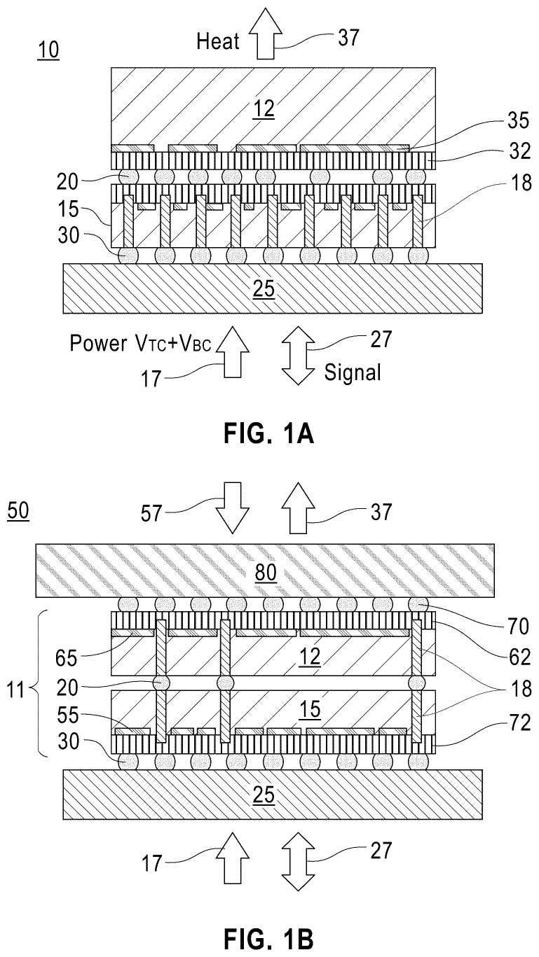

FIG. 1A depicts a cross-sectional view of a conventional semiconductor IC package or module 10 including a flip chip assembly such as a two-die chip stack 11 having a first top IC chip 12 electrical connected to a top surface of a bottom IC chip 15 through a series of C4 or solder bump connections 20 aligned to connect exposed conductors at each chip 12, 15. In the cross-sectional view of FIG. 1A, the bottom IC 15 of the flip chip electrically connects to a substrate, such as an organic laminate 25 via a series of C4 or solder bump connections 30. The bottom IC chip 15 includes a series of Through Silicon Via (TSV) structures 18 that carry power, logic and/or data signals from the laminate to the bottom IC chip 15 and top chip 12. Electrical signals such as direct current (DC) power signals 17 for powering both top chip 12 and bottom chip 15 and logic/data signals 27 conveyed from an external source (not shown) or through the laminate 25 are conveyed via the bumps 30 and corresponding TSVs 18 to corresponding bumps 20 and metal interconnect structures 32 formed at both top and bottom chips 12, 15 during back-end-of-line (BEOL) semiconductor chip manufacturing techniques. The TSVs 18 allow for bi-directional flow from the laminate to the bottom IC chip 15 and from the top or bottom IC chip through to conductors at the laminate 25. In the embodiment depicted in FIG. 1A, at least the top chip BEOL interconnects structures 32 electrically connect with conductors of a fabricated hardware macro 35 which can be a microprocessor core, a microcontroller, a signal processor, a graphics and/or multimedia processor, or an electronic memory core. In the conventional packaging design of FIG. 1A, heat 37 generated at the chips 12, 15 is shown being dissipated via the top surface of the chip 12.

FIG. 1B depicts a cross-sectional view of a further conventional semiconductor IC package or module 50 including a flip chip assembly or multi- or two-die chip stack 11 having a first top IC chip 12 and bottom IC chip 15 in the two-die stack arrangement that is electrically connected to each other via specifically located C4 or solder bumps 20 and TSV conductors 18. In particular, BEOL interconnect structures 72 formed at the bottom surface of the bottom IC chip 15 of the two-die chip stack 11 connect chip hardware macros 55 of the bottom chip 15 to the substrate or organic laminate 25 via TSV conductor structures 18 and bumps 30. Further, in the chip module 50 depicted in FIG. 1B, BEOL interconnect structures 62 connecting to hardware macros 65 formed near the top surface of the top chip 12 connect to the thermal power plane 80 via connecting C4 or solder bumps 70 shown formed at the top surface of the top chip 12.

As in the embodiment of FIG. 1A, electrical signals such as direct current (DC) power signals 17 for powering both top chip 12 and bottom chip 15 and logic/data signals 27 conveyed from an external source (not shown) or through the laminate 25 are conveyed via the bumps 30 and corresponding TSVs 18 to corresponding bumps 20 and metal interconnect structures 32 that are formed at both top and bottom chips 12, 15 during back-end-of-line (BEOL) semiconductor chip manufacturing. The TSVs 18 allow for bi-directional flow to/from the laminate from/to the bottom IC chip 15 and to/from the top or bottom IC chip through conductors (not shown) at the laminate 25.

In the module 50 of FIG. 1B, a further structure referred to as a “thermal power plane” 80 is disposed which is a thermally conductive structure connecting with top BEOL interconnect layer 62 via a series of further C4 or solder bumps 70 located at the top surface of the top IC chip 12. In an embodiment, the “thermal power plane” is a coreless laminate of about 200 μm to 400 μm thick situated above the top surface of top chip 12 that connect to the formed interconnects of BEOL interconnect layer 62 via solder bumps 70 and functions as both a means of power delivery of power signals 57 to the top IC chip 12 and also as a heat spreader for spreading/dissipating of heat 37 generated by the two-die chip stack 11. As known, typical organic material laminates have a centralized core to add rigidity to the substrate and typically has a low CTE (e.g., smaller than 15 ppm/° C. in x, y directions and smaller than 33 ppm/° C. in z directions). The core is provided with the power planes used to deliver the power signals up to the IC chips. However, it is the case that the thermal resistance of a coreless laminate (i.e., thermal power plane) 80 cannot be so small such that compatibility between power delivery and thermal management from the chip top side is not fully achievable.

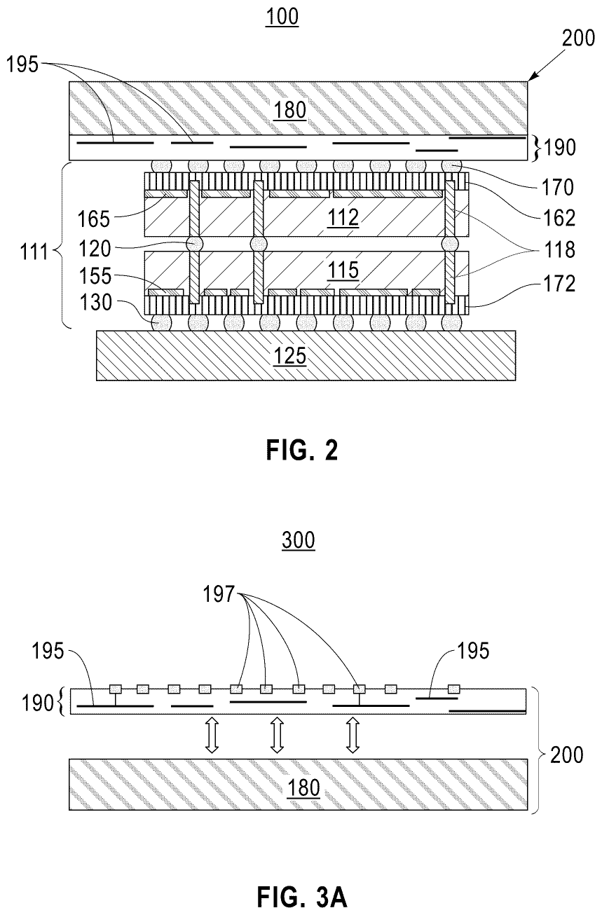

FIG. 2 shows an improved embodiment of a semiconductor chip package or module 100 that includes a flip chip assembly consisting of a 3-dimensional chip stack such as a two-die chip stack 111 including a top IC chip 112 and bottom IC chip 115 and including a combined redistribution layer RDL/heat spreader structure according to an embodiment. Although a two-die chip stack 111 is shown, the flip chip assembly can be a multi-die chip stack formed using conventional processes. Similar to the prior embodiment of FIG. 1B, the top IC chip 112 and bottom IC chip 115 of the two-die chip stack 111 are electrically connected to each other via specifically located C4 or lead free solder bumps 120 or copper to copper bonding (e.g., pad to pad, etc.). In an embodiment, the solder bumps can be a lead-free solder material such as Sn, Ag, Cu, Bi or alloys thereof. Each chip is further formed to include TSV conductors 118 for conveying signals vertically between each chip. With more particularity, BEOL interconnect structures 172 formed at the bottom surface of the bottom IC chip 115 of the two-die chip stack 111 connect chip hardware macros 155 of the bottom chip 115 to a substrate or organic laminate 125. Top IC chip 112 includes hardware macros 165 and can connect to bottom chip hardware macros via TSV conductor structures 118 and C4 or solder bumps 120 and further can connect to conductive structures in the laminate 125 via TSV 118 and C4 or solder bumps 130. Further, in the chip module 100 depicted in FIG. 2, BEOL interconnect structures 162 connect to hardware macros 165 formed near the top surface of the top chip 112.

In the embodiment of the structure 100 depicted in the cross-sectional view of FIG. 2, there is further disposed a separately formed power delivery and heat dissipating structure 200 consisting of a heat spreader layer 180 of a metal material and underlying dielectric redistribution layer (RDL) 190 having formed conductor wiring structures 195 formed therein Both heat spreader layer 180 and underlying RDL layer 190 of structure 200 are configured for power delivery and heat spreading. The underlying redistribution layer 190 is a dielectric or insulative layer (e.g., diamond). The BEOL interconnect structures 162 of the top IC chip 112 connect hardware macros to conductive structures 195 formed in one or more layers within the redistribution layer 190 via C4 or solder bumps 170.

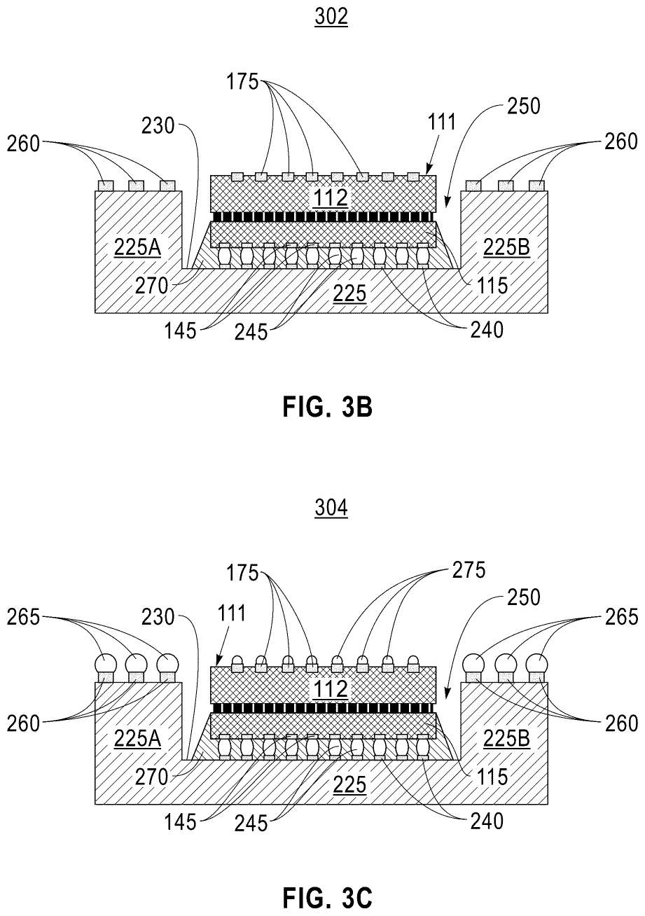

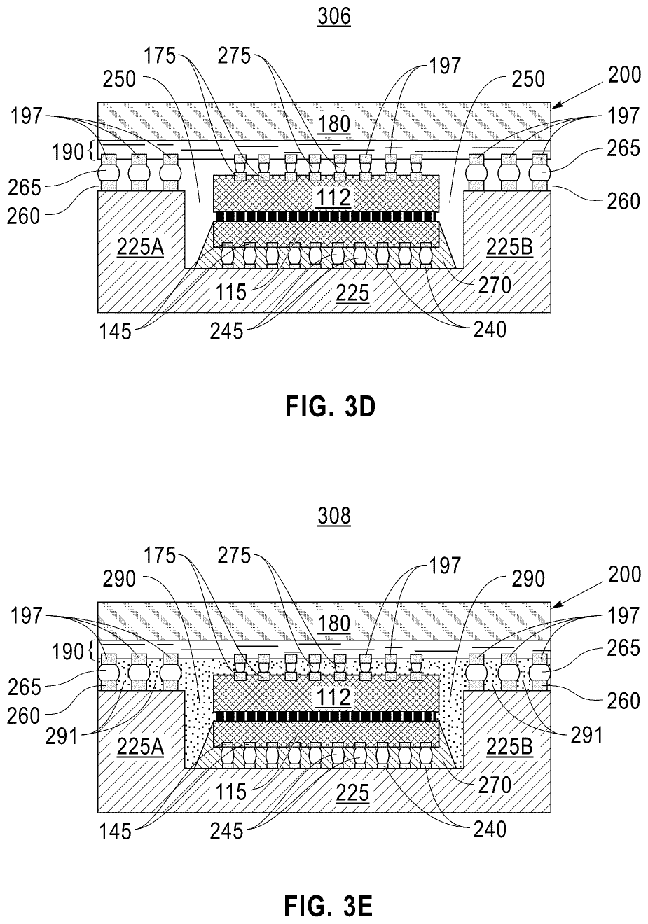

FIGS. 3A-3E depict a method for forming the semiconductor structure 100 of FIG. 2 that includes the flip chip assembly or multi-die or two-die chip stack 111 and the further connected separately formed power delivery and heat dissipating structure 200 consisting of the heat spreader layer 180 and underlying dielectric redistribution layer (RDL) 190 electrically connected to the top surface of the flip chip assembly.

FIG. 3A shows the separate step 300 of forming of the power delivery and heat dissipating structure 200 of FIG. 2. In an embodiment, as shown in the cross-sectional view of FIG. 3A, the heat spreader layer 180 is a heat sink structure consisting of a layer of metal or metal alloy, e.g., Cu, Aluminun, MoCu, SiC, and/or like highly thermal conductive metals or metal alloys, having a thickness ranging anywhere from between 1 mm to 3.5 mm. The redistribution layer (RDL) 190 is a highly thermally conductive dielectric material layer formed on top the heat spreader layer and is of a thickness that can range anywhere from between 1-400 microns and can include one or more layers (e.g., up to eight thin wiring layers) of conductors 195 for conveying and distributing the power and/or ground signals from the laminate to different locations at the top IC chip. This RDL layer 190 is designed to be thinner than a coreless laminate structure and each wiring layer 195 of RDL 190 can range anywhere from between 1 μm-400 μm thick and has a very high thermal conductivity dielectric material, e.g., >1 Watt/m/° C. In addition, conductors 195 can include signal distribution wiring for conveying I/O data/logic signals to the chips. In an embodiment, heat spreader layer 180 is formed on a semiconductor wafer and the redistribution layer 190 is a layer of dielectric material formed on the heat spreader 180, using a photolithographic manufacturing techniques. In a non-limiting embodiment, the redistribution layer 190 is a dielectric material layer such as diamond film (diamond-like carbon) which is both highly thermally conductive and is electrically insulating. Preferably, dielectric materials used to form RDL layer 190 include, but are not limited to: silicon dioxide, silicon nitride, silicon oxynitride, boron nitride, aluminum nitride, beryllium oxide, or any multilayered combination thereof having thermal conductivity greater than tens or hundreds of Watt/m/° C. The dielectric material layer forming RDL 190 includes one or more embedded wire conductors, e.g., metal wires or traces 195 and connect with electric contact pads 197 (or like conductive terminals or connectors) that are exposed for eventual electrical connection to other structures or devices, e.g., for receiving signals such as power and/or ground signals or I/O data/logic signals, according to embodiments herein. In embodiments, conductive metal wires 195 can include copper or aluminum or other like metals or alloys thereof. In an embodiment, the RDL layer 190 include conductor wires 195 and conductive connectors or pads 197 that can re-route any power or logic/data of an I/0 layout into a looser pitch footprint, for example. In a non-limiting embodiment, such redistribution layer 190 can further include thin film polymers such as BCB, PI or other organic polymers and metallization such as Al or Cu to reroute received power/ground signals received at the conductive connectors or pads 197.

In an embodiment, as shown in FIG. 3A, RDL layer 190 conventional BEOL semiconductor manufacturing techniques includes the forming of the connector pads 197 at a surface of the dielectric layer that are electrically connected to the wires 195 and which configured, is oriented, e.g., flipped, in a manner to align with and electrically connect to corresponding top electrical connector elements such as C4 or solder bumps 170 at a top surface of top chip 112 as shown in FIG. 2. Additionally, the formed connector pads 197 at a surface of the dielectric layer 190 are located to electrically connect to corresponding top electrical connector elements such as C4 or solder bumps formed at a top surface of a laminate or substrate outside the flip chip IC stack 111 as shown in FIG. 3D. In embodiments, the heat spreader 180 and RDL layer 190 can be separate formed and the RDL layer transferred and subsequently joined to the heat spreader.

FIGS. 3B-3E depict further method steps for electrically connecting the power delivery and heat dissipating structure 200 including R.DL and heat spreader layers to one or more of: a laminate below a chip, at the peripheral of a chip, for distributing the power and ground to the top side of the flip chip IC stack 111.

FIG. 3B depicts a resulting structure 302 after assembling a flip-chip two-die (or multi-die) chip stack 111 including top chip 112 connected to bottom chip 115 that have been joined, e.g., implementing a flip chip joining process, and after connecting the flip-chip two-die or multi-die chip stack 111 to a laminate or substrate structure 225. In the embodiment of FIG. 3B, the two-die chip stack 111 provides for dual-side electrical interconnects (EIC) to the chip stack. As particularly shown in FIG. 3B, in an embodiment, the provided substrate 225 can be an organic laminate substrate (or laminate structure), printed wiring board (PWB), interposer, etc., and that includes two raised portions 225A, 225B defining a cavity 250 therein. Within cavity 250 is physically joined the two-die or multi-die chip stack 111 and which is electrically connected to exposed conductors at a surface 230. In a non-limiting illustrative embodiment, the laminate structure 225 is initially assembled using conventional production processes that include forming the laminate structure 225 to include a topography having raised portions 225A, 225B defining a cavity 250 therebetween. In an embodiment, the laminate structure has a metal core (or a ceramic core or a diamond core) and/or embedded graphite sheets (not shown). The bottom surface 230 of the laminate cavity 250 is formed with conductive pad or bump features 240 including corresponding solder balls or bumps 245 of a bump pitch, e.g., 50 microns-150 microns pitch, designed to align with corresponding bump pad features of the bottom IC chip of the two-die or multi-die chip stack 111. In an embodiment, the multi-die chip stack 111 is picked, aligned with and placed within cavity 250 for physical connection thereto using a conventional solder reflow or compression bonding process. Similarly formed a top of each of the raised laminate portions 225A, 225B are a further series of conductive pads or bump features 260 that are designed of a pitch for eventual connection to the power delivery and heat dissipating structure 200.

The resulting structure 302 depicted in FIG. 3B. further depicts the results of attaching the two-die or multi-die chip stack 111 to the bottom surface of the cavity at bumps 245. Particularly, structure 302 results from an applied solder reflow process that electrically connects aligned flip-chip bump or pads 145 on a bottom surface of the bottom chip 115 of stack 111 to the corresponding aligned bump pads 240 and solder bumps 245 by the solder reflow process. In particular, during a solder reflow, upon contact of a ball 245 to a laminate feature 240 e.g., the ball will collapse and form an electrical interconnection or joint. As further shown in FIG. 3B, the top surface of top chip 112 is formed with exposed bumps/pads 175 which can be of a different pitch and/or size of the pads 145 at the bottom flip-chip bump on the bottom surface of the bottom chip 115 of stack 111.

In embodiments, as further shown in FIG. 3B, the resulting structure 302 is shown to include the result of dispensing or flowing within cavity 250 a flip-chip underfill or a curing material or molding compound material 270 between the IC chip stack 111 and the substrate laminate cavity surface 230 to enhance thermal conductivity and mechanical stability to improve bonding of the bottom IC chip to the laminate. Such underfill material 270 can include a filler in a polymer substance that can be cured to a solid composite with a desired coefficient of thermal expansion (CTE) value and can fill completely underneath the chip stack 111 to the laminate and up a sidewall at each edge of the chip assembly 111.

FIG. 3C depicts a resulting structure 304 after forming C4 or solder bumps 275 on top of each respective formed pads 175 on the top surface of the top chip 112 of the flip-chip two-die (or multi-die) chip stack 111 and after forming C4 or solder bumps 265 on top of each respective formed pads 260 on the top surfaces of each of the raised laminate portions 225A, 225B. Although both raised laminate portions 225A, 225B are shown having respective pad and solder bump connections, it is the case that only a single raised laminate portion can include pad and solder bump connections for connection to the power delivery and heat dissipating structure 200. The layout of pads 175 and corresponding solder bumps 275 at the top chip 112 of stack 111 are configured to align with interconnect pads of the RDL layer of the power delivery and heat dissipating structure 200. Similarly, the layout of pads 260 and corresponding solder bumps 265 at the top surface of one or both raised laminate portion 225A, 225B are located to align with further interconnect pads at the underside of the RDL layer of the power delivery and heat dissipating structure 200. In an embodiment, the height of the raised laminate portions 225A, 225B and top bumps 265 at the surface of the raised laminate portions of substrate 225 are designed to lie at an equal elevation or same height as each of the top bumps 275 at the top chip 112 of stack 111.

FIG. 3D depicts a resulting structure 306 after joining the power delivery and heat dissipating structure 200 to the top chip of stack 111 and on one or both of the raised laminate portions 225A, 225B. In particular, in a subsequent packaging assembly process, the pads 197 formed on the underside surface of the RDL layer 190 are aligned with the respective pads and bumps 175, 275 of the top chip 112 of the flip-chip two-die (or multi-die) chip stack 111 and are aligned with the respective pads and bumps 260, 265 on top of each of the top surfaces of each of the raised laminate portions 225A, 225B. Alternately, the RDL 190 may be formed with solder balls for further connection to the top chip 112 of chip stack 111. A solder reflow process is then formed to affix the power delivery and heat dissipating structure 200 to the structure of FIG. 3C such that the pads 197 formed on the underside surface of the RDL layer 190 physically join with the respective aligned pads and bumps 175, 275 of the top chip 112 of the flip-chip stack 111 and further electrically connect with the respective aligned pads and bumps 260, 265 on top of one or both of the top surfaces of each of the raised laminate portions 225A, 225B.

FIG. 3E depicts a resulting structure 308 after a dispensing of the same or different highly thermal conductive underfill or molding compound 290 that fills the remaining portions of the cavity 250. In an embodiment underfill material can be an epoxy polymer or resin with fused silica, ceramic or other material filler as known in the art. The resulting semiconductor package structure 308 significantly achieves both efficient power delivery and thermal management and further realizes power delivery and thermal management from the IC chip top side. As shown in FIG. 3E, the spaces 291 between the electrical interconnects connecting the laminate raised peripheral portions to underlying conductive pads at the RDL layer 190 is filled with the highly thermal conductive material (underfill, molding compound) 290.

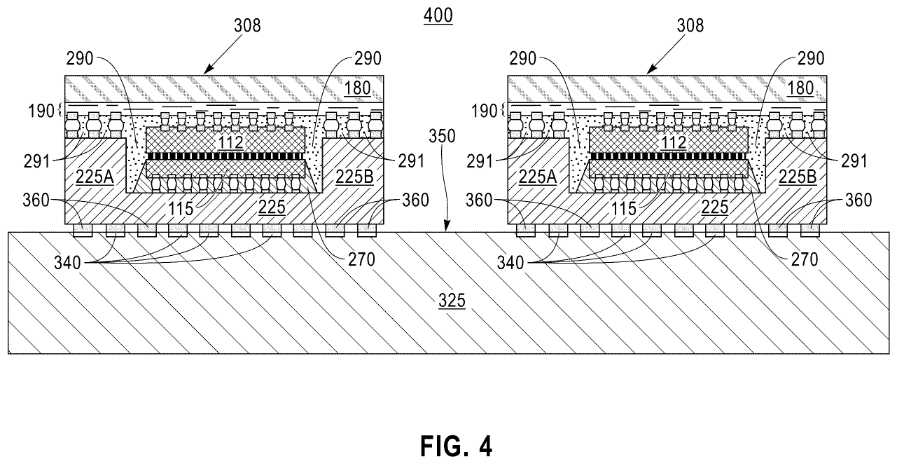

FIG. 4 depicts a further structure 400 resulting from further packaging and assembly to attach one or more structures 308 of FIG. 3E to a printed wiring board or printed circuit board 325, e.g., using a solder reflow process. In particular, the bottom surface of laminate 225 is prior formed with exposed electrical pads or connectors 360 that can connect to corresponding aligned conductive connectors or pads 340 exposed at a top surface 350 of the PWB. These connections 340 at the PWB board 325 connect to PWB wiring (not shown) that enable routing of signals between each of the one or more structures 308 and/or for connection to other modules, circuits, power sources or ground connections (not shown).

The described aspects and examples of the present disclosure are intended to be illustrative rather than restrictive, and are not intended to represent every aspect or example of the present disclosure. While the fundamental novel features of the disclosure as applied to various specific aspects thereof have been shown, described and pointed out, it will also be understood that various omissions, substitutions and changes in the form and details of the devices illustrated and in their operation, may be made by those skilled in the art without departing from the spirit of the disclosure. For example, it is expressly intended that all combinations of those elements and/or method steps which perform substantially the same function in substantially the same way to achieve the same results are within the scope of the disclosure. Moreover, it should be recognized that structures and/or elements and/or method steps shown and/or described in connection with any disclosed form or aspects of the disclosure may be incorporated in any other disclosed or described or suggested form or aspects as a general matter of design choice. Further, various modifications and variations can be made without departing from the spirit or scope of the disclosure as set forth in the following claims both literally and in equivalents recognized in law.

What is claimed is:

1. An apparatus comprising:
a substrate having conductors for carrying signals;
a semiconductor integrated circuit (IC) chip mounted on and electrically connected to exposed conductors at said substrate for receiving signals therefrom;
a redistribution layer (RDL) of high thermal conductive material connected to a top surface of said IC chip, said RDL having connector structures for electrical connection with conductors of said substrate for receiving signals from the substrate and distributing the signals to said IC chip; and
a thermally conductive heat spreader structure disposed on top said RDL layer for receiving, distributing and dissipating heat from a top surface of the RDL.

2. The apparatus as claimed in claim 1, wherein the signals received at the RDL are one or more of: power signals for powering the IC chip or logic signals or data signals for receipt at the IC chip.

3. The apparatus as claimed in claim 2, wherein the RDL is a dielectric material layer including wire conductors therein for redistributing the signals received from the substrate for input to the IC chip.

4. The apparatus as claimed in claim 1, wherein the thermally conductive heat spreader structure is a metal layer or metal alloy layer.

5. The apparatus as claimed in claim 1, wherein the substrate is a coreless organic laminate structure or an organic laminate having one of: a metal core, a ceramic core, or a diamond core, and/or one or more embedded graphite sheets.

6. The apparatus as claimed in claim 5, wherein the coreless organic laminate structure comprises:
a first raised laminate portion and a second raised laminate portion spaced apart from said first raised laminate portion to define a cavity therebetween, wherein the IC chip is mounted within said cavity for electrical connection with conductors exposed at a surface of said cavity.

7. The apparatus as claimed in claim 6, wherein said RDL connector structures comprise: solder bump connections joined to the corresponding conductive connections at a surface of each said first raised laminate portion and said second raised laminate portion said substrate, said apparatus further comprising: a high thermally conductive underfill material filling said cavity and spaces between the solder bump connections.

8. The apparatus as claimed in claim 1, wherein the IC chip is a 3-dimensional flip-chip stacked assembly comprising a dual-die stack or multi-die stack of integrated circuit chips.

9. The apparatus as claimed in claim 8, wherein the substrate delivers power signals and ground directly to a bottom IC chip of the flip-chip stack assembly and to a top IC chip of the flip-chip stack assembly through said RDL.

10. The apparatus as claimed in claim 9, further comprising: a printed wiring board upon which the substrate is mounted and electrically connected therewith.

11. An apparatus comprising:
an organic laminate substrate having spaced apart raised laminate portions to define a cavity therebetween, said organic laminate substrate including conductive connectors at a surface of said cavity and at a surface of one of said raised laminate portions for carrying signals;
a semiconductor integrated circuit (IC) chip mounted within said cavity and electrically connected to exposed conductors at a surface of said cavity, the IC chip having top surface conductive connections; and
a layered structure comprising:
a redistribution layer (RDL) of high thermal conductive material disposed overlying said IC chip and overlying at least one of said spaced apart raised laminate portions, said RDL having a bottom surface with conductor elements electrically connecting to corresponding aligned conductive connections at a top surface of the IC chip and further connected to the conductive connectors at a top surface of said raised laminate portion and having conductors for redistributing signals received from the organic laminate substrate for input to the IC chip; and
a heat spreader layer disposed on a top surface of said RDL layer for receiving, distributing and dissipating heat from the top surface of the RDL.

12. The apparatus as claimed in claim 11, wherein said layered structure overlies two spaced raised laminate portions, said RDL bottom surface having further conductor elements electrically connected to the conductive connectors at a top surface of each said raised two spaced apart raised laminate portions.

13. The apparatus as claimed in claim 12, wherein said RDL electrical conductor elements comprise: solder bump connections joined to the corresponding aligned conductive connections at the top surface of the IC chip and further connected to the conductive connectors at a top surface of the raised laminate portion, said apparatus further comprising: a high thermally conductive underfill material filling said cavity and spaces between the joined solder bump connections.

14. The apparatus as claimed in claim 11, wherein said organic laminate substrate is a coreless laminate or a laminate having one of: a metal core, a ceramic core, or a diamond core, and/or one or more embedded graphite sheets.

15. The apparatus as claimed in claim 11, wherein the mounted IC chip is a 3-dimensional flip-chip stack assembly comprising a dual-die stack or multi-die stack of integrated circuit chips, said organic laminate substrate delivering power signals and ground directly to a bottom IC chip of the flip-chip stack assembly and to a top IC chip of the flip-chip stack assembly through said RDL.

16. The apparatus as claimed in claim 11, further comprising: a printed wiring board upon which the organic laminate substrate is joined for electrical connection therewith.

17. A method for manufacturing a flip-chip package comprising:
fabricating a redistribution layer (RDL) of high thermal conductive material on a heat spreader structure;
physically joining, to an organic laminate substrate, a semiconductor flip-chip stack assembly comprising at least a top integrated circuit (IC) chip and a bottom IC chip, the organic laminate substrate having spaced apart raised laminate portions to define a cavity therebetween, wherein said semiconductor flip-chip stack assembly bottom IC chip is joined at the defined cavity for electrical connection to said organic laminate substrate; and
physically joining the fabricated redistribution layer (RDL) and heat spreader structure on a top surface of the top IC chip and a top surface of each said raised laminate portions of the organic laminate substrate for electrical connection therewith, wherein the RDL comprises a bottom surface with conductor elements electrically connecting to corresponding aligned conductive connections at a top surface of the top IC chip and further connected to the conductive connectors at a top surface of said raised laminate portions and comprises conductors for redistributing signals received from the organic laminate substrate for input to the top IC chip.

18. The method as claimed in claim 17, wherein the physically joining of the semiconductor flip-chip stack assembly to the defined cavity of the organic laminate substrate comprises:
forming solder bump connections at locations for joining corresponding conductive connectors at a surface of said cavity with corresponding conductive connectors located at a bottom surface of the bottom IC chip;
aligning the formed solder bump connections at the corresponding conductive connectors at the surface of said cavity with corresponding conductive connectors located at the bottom surface of the bottom IC chip;
performing a solder reflow process for physically joining the bottom IC chip of the semiconductor flip-chip stack assembly to the corresponding conductive connectors at the surface of said defined cavity for electrical connection therewith; and
dispensing a high thermally conductive underfill material within the cavity to enhance mechanical and thermal stability of the joined solder bump connections at the exposed surface of said cavity with corresponding conductive connectors located at a bottom surface of the bottom IC chip.

19. The method as claimed in claim 17, wherein the physically joining of the fabricated redistribution layer (RDL) and heat spreader structure on a top surface of the top IC chip and a top surface of each said raised laminate portions of the organic laminate substrate comprises:
forming solder bump connections at locations for joining corresponding conductive connectors at a top surface of said top IC chip and corresponding conductive connectors at a top surface of each said raised laminate portions with corresponding conductive connectors located at a bottom surface of the redistribution layer (RDL) and heat spreader structure;
aligning the formed solder bump connections at the corresponding conductive connectors at a top surface of said top IC chip and corresponding conductive connectors at a top surface of each said raised laminate portions with corresponding conductive connectors located at a bottom surface of the redistribution layer (RDL) and heat spreader structure;
performing a solder reflow process for physically joining the corresponding conductive connectors at a top surface of said top IC chip and corresponding conductive connectors at a top surface of each said raised laminate portions with corresponding conductive connectors located at a bottom surface of the redistribution layer (RDL) and heat spreader structure for electrical connection therewith; and
dispensing further high thermally conductive underfill material within the cavity to enhance mechanical and thermal stability of the joined solder bump connections at the top surface of said top IC chip and corresponding conductive connectors at a top surface of each said raised laminate portions of the organic laminate substrate.

20. The method as claimed in claim 19, further comprising:
joining the organic laminate substrate to a printed wiring board for electrical connection therewith.
